(19) United States
(12) Patent Application Publication
(10) Pub. No.: US 2009/0074199 A1
(43) Pub. Date: Mar. 19, 2009

(54) SYSTEM FOR PROVIDING A REDUCTION OF AUDIABLE NOISE PERCEPTION FOR A HUMAN USER

(75) Inventors: Lau Kofoed Kierstein, Vejle (DK); Jorn Eskildsen, Torring (DK)

Correspondence Address: CANTOR COLBURN, LLP, 20 Church Street, 22nd Floor, Hartford, CT, 06103, US

(73) Assignee: MAYSOUND APS, Vejle (DK)

(21) Appl. No.: 12/089,138

(22) PCT Filed: Sep. 29, 2006
(86) PCT No.: PCT/DK2006/000537

§ 371 Date: Nov. 5, 2008

(30) Foreign Application Priority Data
Oct. 3, 2005 (EP) 05077242.5

(51) Int. Cl. H03B 29/00

(52) U.S. Cl. 381/71.6

(57) ABSTRACT

A system is disclosed where the well-known psycho-acoustic masking effect, i.e. frequency and/or temporal masking is applied to reduce the human perception of a noise signal. An input signal, such as music or another entertainment signal, is adjusted based on the intensity of the auditory noise by applying existing knowledge about the properties of the human auditory perception and is provided to the human user as a masking sound signal, so that the masking sound elevates the human auditory perception threshold for at least some of the noise signal, whereby the user's perception of that part of the noise signal is reduced or eliminated. The masking sound may be combined with active noise control where a sound in anti-phase with the noise signal is provided for further reduction of the human perception of the noise signal.

### FIELD

The present invention relates to reduction of the perception of an auditory noise from the environment for a human user by emission of a second sound.

### BACKGROUND

Auditory noise, e.g. undesired sound is present in many environments. Without some effective reduction or removal of the perception of undesired sound emitted, e.g., by snoring, traffic etc., many modern environments would be largely intolerable to people, be it the household, the office, the inside of a vehicle, or an airport hotel.

In many instances, however, noise creating sources cannot be eliminated or reduced sufficiently by passive sound isolation, and the effort is aimed at transmitting a cancelling sound which reduce or eliminate the human perception of the undesired sound.

A system of this kind is for example known from DE 197 06 645 which discloses an invention for emitting a anti-phase sound signal to a snoring sound by means of an active noise control system.

U.S. Pat. No. 5,844,996 discloses another invention for attenuation of snoring noise sensed by the auditory nerve by using an active noise control as a method for transmitting a cancelling sound. The system reverses the phase of the frequencies of the detected snoring so as to provide destructive interference of the snoring noise and emits these as the cancelling sound. The system also comprises a correction function based on the actual snoring sound and the emitted cancelling sound, called adaptive active noise control.

EP 0 512 445 discloses an invention for adaptive active noise control where a calibration sound signal is emitted for the purpose of improving the computation of the adaptive algorithm of the active noise control. This calibration signal is mixed with an entertainment signal, for example music, for the purpose of wholly or partially masking of the calibration signal.

### BRIEF DESCRIPTION

It has been realised by the present invention that the well-known psycho-acoustic masking effect, i.e. that a sound due to another sound may become partially or completely inaudible, may be used to reduce or even eliminate the human perception of an auditory noise by providing a masking sound to the human user, where the intensity of an input signal, such as music or another entertainment signal, is adjusted based on the intensity of the auditory noise by applying existing knowledge about the properties of the human auditory perception and is provided to the human user as a masking sound signal, so that the masking sound elevates the human auditory perception threshold for at least some of the noise signal, whereby the user's perception of that part of the noise signal is reduced or eliminated.

The present invention may e.g. be applied for reducing the perception of snoring sound, traffic noise etc.

The masking effect is known in the area of psycho-acoustics, and relates to how the lower limit or threshold of the human sound perception with respect to sound intensity and/or frequency contents is elevated.

Today, the knowledge of the psycho-acoustic masking effect is applied in compression algorithms for compressing data files representing sound, such as music, by identifying the parts of the sound that are not perceived by the human listener and remove those parts from the data. Another application is to determine the auditory perception threshold generated by a given sound signal and add white noise below the threshold, so that a feed-back signal with broader contents in the frequency domain may be provided to an adaptive processing system for providing the sound signal, whereby an improved adaptation process is obtained, e.g. for reducing or eliminating echoes in a speech signal as disclosed in U.S. Pat. No. 6,556,682.

In U.S. Pat. No. 6,556,682, frequency masking, also known as simultaneous masking is applied. There is a threshold, called the frequency masking threshold, below which all the frequency components of a masked sound are inaudible. For more detail on this masking phenomenon, reference is made to the work by E. ZWICKER and R. FELDTKELLER entitled “Das Ohr als Nachrichtenempfänger”, Stuttgart, West Germany, Hirzel Verlag, 1967. Another type of masking is temporal masking, also called time masking, where the intensity threshold for the audible sound intensity is temporarily elevated by a more intensive sound.

Thus, the present invention relates to a system for providing a reduction of auditory noise perception for a human user, comprising a signal processing unit, means for providing a first input signal to the signal processing unit, such as music or another entertainment signal, and at least one microphone for providing a second input signal representative of said auditory noise to the signal processing unit, the signal processing unit comprising masking means for providing an output signal to at least one loudspeaker so as to provide a masking sound signal by the loudspeaker to the human user, wherein the masking means of the signal processing unit is adapted to provide a psycho-acoustic masking effect to the human user with respect to the said auditory noise by comprising means to form the output signal by an adjustment of the intensity of the provided first input signal, the adjustment being based on the intensity of the second input signal and properties of the human user's auditory perception, so that the masking sound signal provided by the loudspeaker is suited to elevate the human auditory perception threshold of at least a part of the auditory noise represented by the second input signal to a level that reduces or eliminates the perception thereof by the human user.

It may, depending on the source of the noise, be advantageous to use more than one microphone to pick up the noise signal and to arrange such microphones with a mutual distance. Also the number of loudspeakers may be higher than one, depending on the specific use of the system.

The adjustment is in a preferred embodiment of the present invention a frequency-dependent adjustment of the intensity of the provided first input signal, wherein the adjustment is based on the intensity of the second input signal with respect to the frequencies thereof and properties of the human auditory perception, so as to provide a frequency masking by means of the masking sound signal for the human user of the system of at least a part of the auditory noise detected by the at least one microphone. It is particularly preferred that the signal processing unit performs the adjustment of the output signal by subjecting the intensity of a plurality of frequency bands of the provided first input signal to individual adjustments.

The signal processing unit may for this purpose comprise means for analysing the power density spectrum of the second input signal, i.e. the intensity thereof distributed on a plurality of frequency bands, and the power of given frequencies of the second signal are applied to determine the frequency-dependent adjustment of the intensity of the provided first input signal for frequencies of the first input signal corresponding to said given frequencies of the second input signal reduced with about one third of an octave, such as to 70-92% thereof, preferably to 75-90% thereof and most preferred to 80-87% thereof. Hereby, the frequency masking effect of the masking sound signal will have a better fit with the noise signal.

Alternatively, the first input signal consists of a plurality of separate signals, each having a frequency contents, which e.g. may contain a predominant frequency band, or the frequency contents of each separate signal may be analysed or known a priori. Each separate signal may e.g. represent a single instrument or group of instruments, and the sum of the separate signal together constituting the first input signal is a piece of music. Instead of dividing the total first input signal into a plurality of frequency bands for individual adjustment, the separate signals may be adjusted in accordance with their frequency content so as to obtain the required masking effect.

Alternatively or additionally, the adjustment of the intensity of the provided first input signal is an intensity-dependent adjustment, so as to provide a temporal masking by means of the masking sound signal for the human user of the system of at least a part of the auditory noise detected by the at least one microphone.

Frequency masking of the noise signal have shown to be more efficient for steady types of noise, whereas peak noise appear to be masked well by temporal masking. The system according to the present invention may operate with either temporal or frequency masking, but it has shown to be advantageous to employ a combination of temporal and frequency masking in order to mask steady-type noise as well as peak noises most efficiently.

The masking of the noise may be combination with other features of the system according to the present invention, such as allowing certain sound signals, such as from a doorbell, a telephone or a crying baby to be perceived by the user, and/or an adaptive system for predicting the development of a sound, e.g. by recognizing the beginning of a snore and adjust the masking sound from the acquired knowledge of the adaptive system about the typical progress of the snore.

In a more advantageous embodiment of the present invention, the masking algorithm or psycho-acoustic masking algorithm is enhanced by providing a feed-back signal to enable adaptive adjustment of the masking, which here is named an adaptive psycho-acoustic masking (APAM). Thus, the system may comprise at least one further microphone arranged for providing the signal processing unit with at least one feed-back signal which represents the sound that reaches the user of the system, and the signal processing unit comprises means to adapt the adjustment of the intensity of the provided first input signal in response to said feed-back signal.

In an even more preferred embodiment, the psycho-acoustic masking algorithm of the system is combined with active noise control (ANC). Thereby, weaknesses of the two different methods for reduction of auditory noise perception for a human user are counteracted by the advantages of the other system, and an improved reduction of the perception of the noise is obtained. Thus, the signal processing unit may further comprise means for active noise control providing a second output signal to the at least one loudspeaker based on the second input signal so as to provide a noise-cancelling sound signal by the loudspeaker to the human user, wherein said noise-cancelling sound signal is in anti-phase or counter-phase to at least a part of said auditory noise at the position of the human user so as to reduce or eliminate said auditory noise at said position. The masking sound and the anti-phase sound may be provided by separate loudspeakers, but it is preferred that the sounds are provided by the same one or more loudspeakers.

The active noise control may in a preferred version of the present invention be equipped with a feed-back system for adaptive active noise control (AANC). Thus, the system may comprise at least one further microphone arranged for providing the signal processing unit with at least one feed-back signal which represents the sound that reaches the user of the system, in a preferred embodiment deducted the masking signal, and the signal processing unit comprises means to adapt the performance of the active noise control means in response to said feed-back signal.

The performance of the adaptation of the active noise control algorithm is improved by the combination with the psycho-acoustic masking, i.e. frequency masking and/or temporal masking, in that the masking sound provides a broader frequency spectrum for determining the acoustic response between the one or more loudspeakers and the one or more microphones that pick up the sound that reaches the user and provides the feed-back signal. This acoustic response changes due to alterations of the acoustic properties, e.g. that persons moves within the space that provides the acoustic response, and a fast adaptation to the altered acoustic properties for a broad range of frequencies is important for the efficiency of the adaptive active noise control.

The present invention relates as well to the use of the system disclosed above for reducing the human auditory perception of noise, in particular of noises originating from snoring and to application of the method employed by the system according to the present invention for reducing the human auditory perception of noise.

The present invention furthermore relates to a method of the human auditory perception of noise by means of psycho-acoustic masking according to the present invention as disclosed herein.

### BRIEF DESCRIPTION OF THE DRAWINGS

A preferred embodiment of the present invention is described below with reference to the enclosed drawing of which

FIG. 1 is a block diagram of the system,

FIG. 2 is a block diagram of one element of the system, the adaptive psycho-acoustic masking (APAM) algorithm, and

FIG. 3 is a block diagram of another element of the system, the algorithm for processing the feed-back signal or error signal, where the masking signal is deducted from the error signal and the acoustic response S(Z) between the loudspeaker and the feed-back microphone is calculated.

The system shown in the drawing is for illustration of a preferred embodiment of the present invention and is not to be regarded as limiting for the scope of invention as described in the enclosed claims.

### DETAILED DESCRIPTION

The system of the present embodiment employs three techniques in one system to providing a reduction of auditory noise perception for a human user: Adaptive Active Noise Control (AANC), Adaptive Psycho-acoustic Masking (APAM) and Online Modelling of Room Response (OMRR) to improve the adaptive function of the former two.

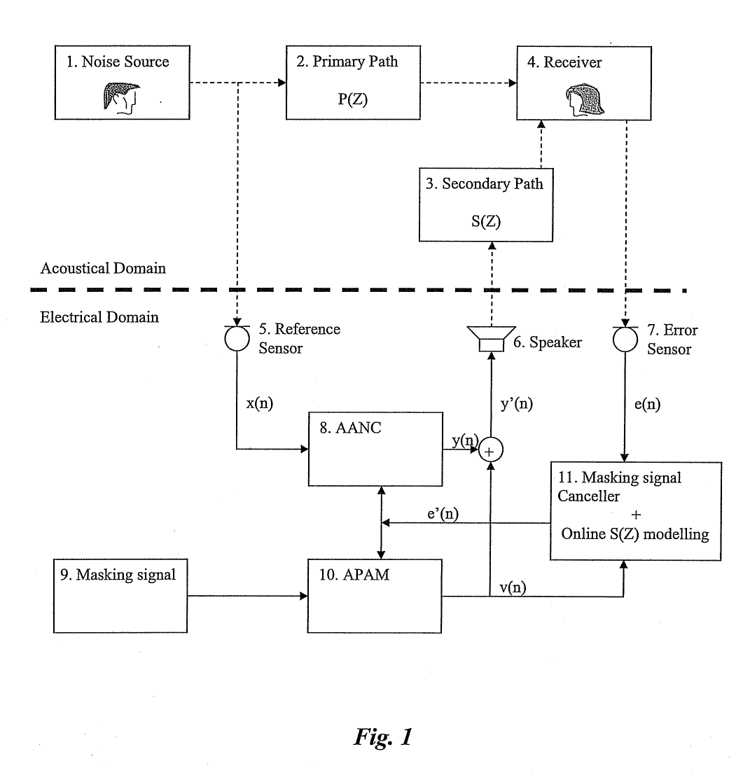

The blocks 1 to 4 in FIG. 1 represents the environment the system is supposed to interact with and would typically be placed in an acoustical domain or environment, such as a room or an enclosure.

The blocks 5 to 11 are situated in an electrical domain or environment, such as an electronic hardware including a Digital Signal Processor.

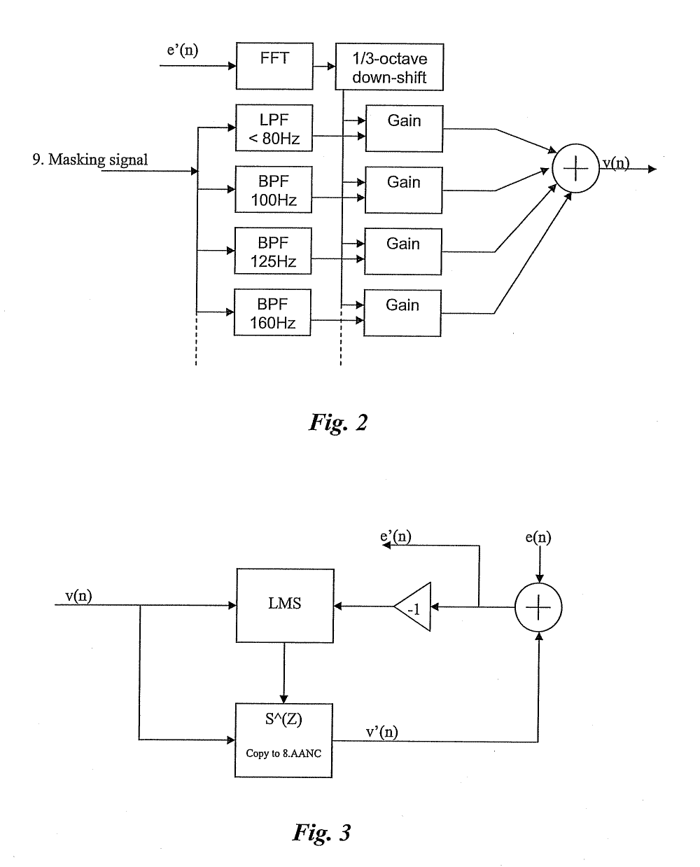

Below is a short description of each block in the overall block diagram in FIG. 1:
1. Noise Source, in the present case exemplified by a snoring spouse. This is the source of the undesired noise sound that the system should try to cancel and mask. The noise may be all different types of noises, e.g. traffic, fan, motor, snoring, etc. The noise source could also be represented in the system as an electrical signal.
2. Primary Path—P(Z). The unknown acoustical response between the 5. Reference sensor and 7. Error sensor. This transfer function is modelled in the 8. AANC adaptive filter W(Z) if a standard feed-forward ANC principle is used.
3. Secondary Path—S(Z). The unknown acoustical response between the 6. Speaker and 7. Error sensor. This transfer function is modelled online in 11. Online S(Z) modelling or may alternatively be determined online in the 8. AANC using the output of 10. APAM and e′(n). This transfer function is determined in order to obtain a fast responding AANC system to chances in the acoustical environment.
4. Receiver, the human user for which the auditory noise perception is to be reduced. The spatial position where the noise signal should be cancelled and masked out according to the perception of a human user.
5. Reference sensor, such as a microphone for providing an input signal x(n) representative of said auditory noise to the signal processing unit. The reference sensor 5 picks up the acoustical noise sound and transforms it into an electrical input signal x(n). This sensor is typically placed near the 1. Noise source or a directional sensor pointing at 1. Noise source. The reference sensor could be one or multiple in numbers depending on the application.
6. Speaker, the one or more loudspeakers for providing a masking sound signal and the noise-cancelling anti-phase sound signal to the human user 4. The speaker transforms the mixture of the noise-cancelling signal and the masking signal into an acoustical sound signal. This element is typically placed near the 4. Receiver or a directional speaker pointing at 4. Receiver. The loudspeaker could be one or multiple in numbers depending on the application.
7. Error sensor, such as one or more microphones. The error sensor picks up the remaining acoustical signal at the receiver and transforms it into a feed-back electrical signal e(n). This sensor is typically placed near the 4. Receiver, or a directional sensor pointing at 4. Receiver to get the most efficient cancellation and masking. The error sensor could be one or multiple in numbers depending on the application.
8. AANC—adaptive active noise control. This is the algorithm performing the calculation of the noise-cancelling signal y(n). The AANC principle is basic and well known.
9. Masking signal. The unfiltered input audio signal used to mask the remaining feed-back signal or error signal, e′(n) after the AANC has taken place. The masking signal could be music or sound effects and could be in one or multiple tracks.
10. APAM. This is the algorithm performing the calculation of the adaptive psycho-acoustic masking signal v(n). The algorithm is using standard psycho-acoustic theory of frequency masking and time masking and adjust its adaptive filters according to the remaining, e′(n), after the AANC has taken place. An example of how the APAM may function is shown in FIG. 2, where the incoming masking signal 9 is divided into a plurality of frequency bands by low-pass and band-pass filters (LPF and BPF). The incoming error signal e′(n) is subjected to a Fast Fourier Transformation (FFT) in order to determine a power density spectrum of the error signal e′(n). The power density spectrum is subjected to a one-third octave downshift in frequency and is applied to calculate the gain for the corresponding frequency bands of the masking signal, so that the resulting output signal v(n) has a higher intensity in the frequency bands that provides the frequency masking effect on the dominant frequencies of the noise sound.
11. Masking signal Canceller+Online S(Z) modelling. This algorithm has two functions: 1. It separates the error signal e′(n) from the masking signal transmitted through the secondary path S(Z) by means of the adaptive psycho-acoustic masking signal v(n) received from the 11. APAM. 2. It models or determines the secondary path S(Z) simultaneously and provides it to the 8. AANC.

With the presently shown system, the function of the APAM is to reduce the human perception of the remaining error signal e′(n) after the application of the AANC to the primary noise signal x(n). However, the layout of the system may be changed within the scope of the present invention, so that e.g. the APAM is applied to reduce the human perception of the primary noise signal x(n) and the AANC is utilised as a supplement for reducing the error signal e(n). Any other more advanced combination of the two systems APAM and AANC are also within the scope of the present invention.

1. A system for providing a reduction of auditory noise perception for a human user, comprising
a signal processing unit,
means for providing a first input signal to the signal processing unit, and
at least one microphone for providing a second input signal representative of said auditory noise to the signal processing unit,
the signal processing unit comprising masking means for providing an output signal to at least one loudspeaker so as to provide a masking sound signal by the loudspeaker to the human user,
wherein the masking means of the signal processing unit is adapted to provide a psycho-acoustic masking effect to the human user with respect to the said auditory noise by comprising means to form the output signal by an adjustment of the intensity of the provided first input signal, the adjustment being based on the intensity of the second input signal and properties of the human auditory perception, so that the masking sound signal provided by the loudspeaker is suited to elevate the human user's auditory perception threshold of at least a part of the auditory noise signal represented by the second input signal to a level that reduces or eliminates the perception thereof by the human user.

2. A system according to claim 1, wherein the adjustment is a frequency-dependent adjustment of the intensity of the provided first input signal, the adjustment being based on the intensity of the second input signal with respect to the frequencies thereof and properties of the human auditory perception, so as to provide a frequency masking by means of the masking sound signal for the human user of the system of at least a part of the auditory noise detected by the at least one microphone.

3. A system according to claim 1, wherein the adjustment is an intensity-dependent adjustment, so as to provide a temporal masking by means of the masking sound signal for the human user of the system of at least a part of the auditory noise detected by the at least one microphone.

4. A system according to claim 2, wherein the signal processing unit is making the adjustment of the output signal by subjecting the intensity of a plurality of frequency bands of the provided first input signal to individual adjustments.

5. A system according to claim 2, wherein the signal processing unit comprises means for analysing the power density spectrum of the second input signal, and the power of given frequencies of the second input signal are applied to determine the frequency-dependent adjustment of the intensity of the provided first input signal for frequencies of the first input signal corresponding to said given frequencies of the second signal reduced to 70-92% thereof, preferably to 75-90% thereof and most preferred to 80-87% thereof.

6. A system according to claim 1, wherein the system comprises at least one further microphone arranged for providing the signal processing unit with at least one feed-back signal which represents the sound that reaches the user of the system, and the signal processing unit comprises means to adapt the adjustment of the intensity of the provided first input signal in response to said feed-back signal.

7. A system according to claim 1, wherein the signal processing unit further comprises means for active noise control providing a second output signal to the at least one loudspeaker based on the second input signal so as to provide a noise-cancelling sound signal by the loudspeaker to the human user, wherein said noise-cancelling sound signal is in anti-phase to at least a part of said auditory noise at the position of the human user so as to reduce or eliminate said auditory noise at said position.

8. A system according to claim 7, wherein the system comprises at least one further microphone arranged for providing the signal processing unit with at least one feed-back signal which represents the sound that reaches the user of the system, and the signal processing unit comprises means to adapt the performance of the active noise control means in response to said feed-back signal.

9. A system according to claim 1, wherein the first input signal is a pre-recorded signal, in particular an entertainment signal.

10. Use of a system according to claim 1 for reducing the human auditory perception of noise, in particular of noises originating from snoring.

11. Method of providing a reduction of auditory noise perception for a human user, comprising the steps of
providing a first input signal to a signal processing unit,
providing a second input signal representative of said auditory noise to the signal processing unit,
providing an output signal from masking means of said signal processing unit to at least one loudspeaker so as to provide a masking sound signal by the loudspeaker to the human user,
wherein the masking means of the signal processing unit is provides a psycho-acoustic masking effect to the human user with respect to the said auditory noise by forming the output signal by an adjustment of the intensity of the provided first input signal, the adjustment being based on the intensity of the second input signal and properties of the human auditory perception, so that the masking sound signal provided by the loudspeaker elevates the human user's auditory perception threshold of at least a part of the auditory noise signal represented by the second input signal to a level that reduces or eliminates the perception thereof by the human user.

12. Method according to claim 11, wherein the adjustment is a frequency-dependent adjustment of the intensity of the provided first input signal, the adjustment being based on the intensity of the second input signal with respect to the frequencies thereof and properties of the human auditory perception, so as to provide a frequency masking by means of the masking sound signal for the human user of the system of at least a part of the auditory noise detected by the at least one microphone.

13. Method according to claim 11, wherein the adjustment is an intensity-dependent adjustment, so as to provide a temporal masking by means of the masking sound signal for the human user of the system of at least a part of the auditory noise detected by the at least one microphone.

14. Method according to claim 12, wherein the signal processing unit is making the adjustment of the output signal by subjecting the intensity of a plurality of frequency bands of the provided first input signal to individual adjustments.

15. Method according to claim 12, wherein the signal processing unit comprises means for analysing the power density spectrum of the second input signal, and the power of given frequencies of the second input signal are applied to determine the frequency-dependent adjustment of the intensity of the provided first input signal for frequencies of the first input signal corresponding to said given frequencies of the second signal reduced to 70-92% thereof, preferably to 75-90% thereof and most preferred to 80-87% thereof.

16. Method according to claim 11, wherein the system comprises at least one further microphone arranged for providing the signal processing unit with at least one feed-back signal which represents the sound that reaches the user of the system, and the signal processing unit comprises means to adapt the adjustment of the intensity of the provided first input signal in response to said feed-back signal.

17. Method according to claim 11, wherein the signal processing unit further comprises means for active noise control providing a second output signal to the at least one loudspeaker based on the second input signal so as to provide a noise-cancelling sound signal by the loudspeaker to the human user, wherein said noise-cancelling sound signal is in anti-phase to at least a part of said auditory noise at the position of the human user so as to reduce or eliminate said auditory noise at said position.

18. Method according to claim 17, wherein the system comprises at least one further microphone arranged for providing the signal processing unit with at least one feed-back signal which represents the sound that reaches the user of the system, and the signal processing unit comprises means to adapt the performance of the active noise control means in response to said feed-back signal.

19. Method according to claim 11, wherein the first input signal is a pre-recorded signal, in particular an entertainment signal.
